(19) United States
(12) Patent Application Publication
(10) Pub. No.: US 2026/0219311 A1
(43) Pub. Date: Jul. 30, 2026

(54) REAL-TIME THROTTLING FOR TESTING OF SEMICONDUCTOR DEVICES

(71) Applicant: Advantest Corporation, Tokyo (JP)

(72) Inventors: Matthias SAUER, Böblingen (DE); Juergen SERRER, Stuttgart (DE)

(21) Appl. No.: 19/232,750

(22) Filed: Jun. 9, 2025

Related U.S. Application Data
(60) Provisional application No. 63/751,773, filed on Jan. 30, 2025.

(51) Int. Cl. G01R 31/28

(52) U.S. Cl. CPC G01R 31/287; G01R 31/2872

(57) ABSTRACT

In various embodiments, a method comprises for maintaining a target environmental test condition during testing of a device under test (DUT), the method comprising: determining a first intensity level associated with a current block of test data, the first intensity level indicating an amount of resources needed to execute the current block of test data, determining an amount of an activity-modification technique based, at least in part, on the first intensity level, and executing the amount of the activity-modification technique for changing an activity level of the DUT.

### CROSS-REFERENCE TO RELATED APPLICATIONS

This application claims priority benefit of United States Provisional Patent Application titled, “REAL TIME THROTTLING FOR TESTING OF SEMICONDUCTOR DEVICES,” filed on January 30, 2025, and having Serial No. 63/751,773. The subject matter of this related application is hereby incorporated herein by reference.

### BACKGROUND

### Field of the Various Embodiments

This application relates to testing of semiconductor devices and more specifically, to real-time throttling for testing of semiconductor devices.

### Description of the Related Art

Reliable testing systems for semiconductor devices typically include a plurality of probes that are positioned on conductive contact points of a device under test (DUT), such as a semiconductor device, chip, and/or the like. Input test signals are then injected into the DUT using some of the probes and test results (output test signals) are read using others of the probes. The test results can then be compared to expected results to determine whether the DUT is functioning properly.

During the testing of the DUT, it is important to maintain the correct environmental test conditions for the DUT. This helps ensure the DUT is being tested under the correct environmental test conditions so that the test results provide an accurate assessment of the operation of the DUT. The correct environmental test conditions can be specified via environmental targets and ranges, such as a target temperature and temperature range. The actual environmental test conditions should be maintained as closely as possible to the correct environmental test conditions (as specified via the environmental targets and ranges) to avoid under- and overshooting of temperatures and/or other specified environmental conditions during testing of the DUT.

Testing systems typically implement coarse-grained throttling techniques in conjunction with a device cooling system that includes, for example, air fans and/or liquid cooling apparatus. Such conventional testing systems typically analyze sensor data (such as temperature data) during the testing period to determine if the current/actual environmental test conditions are complaint with specified environmental targets and ranges. If the current environmental test conditions at a predetermined time point are not complaint with the specified environmental targets and ranges, the conventional testing systems typically adjust the parameters of the device cooling system, such as increasing or decreasing fan speed and/or the rate of liquid cooling.

However, conventional testing systems typically cannot dynamically and in real time adapt to changes in the behavior of the DUT and/or the actual environmental test conditions, which can exceed the regulation capabilities of such conventional testing systems. This can result in the actual environmental test conditions being above or below the environmental targets and ranges during the testing, thereby resulting in inaccurate test results and an inaccurate assessment of the operation of the DUT.

Accordingly, what is needed are improved techniques for maintaining environmental test conditions when testing semiconductor devices.

### SUMMARY

In various embodiments, a method comprises for maintaining a target environmental test condition during testing of a device under test (DUT), the method comprising: determining a first intensity level associated with a current block of test data, the first intensity level indicating an amount of resources needed to execute the current block of test data, determining an amount of an activity-modification technique based, at least in part, on the first intensity level, and executing the amount of the activity-modification technique for changing an activity level of the DUT.

At least one technical advantage of the disclosed techniques relative to the prior art is that the disclosed automated testing techniques provide continuous and real-time adjustments for an activity level of the DUT to ensure the correct/target environmental test conditions are maintained during the entire testing period. The techniques include a fine-grained feedback loop that continuously determines any difference/delta between the current environmental test conditions and the correct/target environmental test conditions, and continuously adjusts the activity level of the DUT using one or more activity-modification techniques. The techniques allow the activity level of the DUT to be adjusted continuously and/or in real-time to maintain the correct environmental test conditions more effectively relative to prior testing systems that implement coarse-grained throttling techniques that typically cannot continuously maintain the correct environmental test conditions throughout the testing period.

Another technical advantage is that the disclosed testing system determines the extent of the one or more activity-modification techniques based on the computed difference/delta with the correct environmental test conditions, intensity levels of a current block and one or more future blocks of test data, characteristics of the particular DUT, the testing system, and/or the testing environment, and/or one or more predictive factors, which causes more accurate changes to the current environmental test conditions relative to prior testing systems that only considered the computed difference/delta with the correct environmental test conditions. As such, the disclosed techniques can proactively anticipate changes in the environmental test conditions providing better control of the environmental test conditions before the environmental test conditions are out of a target range of the correct environmental test conditions. A further technical advantage is that the disclosed testing system can implement one or more activity-modification techniques that involve directly regulating the control parameters of the DUT which provide greater ability to change the current environmental test conditions relative to prior testing systems that only adjusted the parameters of the device cooling system. These technical advantages provide one or more technological advancements over prior art approaches.

### BRIEF DESCRIPTION OF THE DRAWINGS

So that the manner in which the above recited features of the various embodiments can be understood in detail, a more particular description of the inventive concepts, briefly summarized above, may be had by reference to various embodiments, some of which are illustrated in the appended drawings. It is to be noted, however, that the appended drawings illustrate only typical embodiments of the inventive concepts and are therefore not to be considered limiting of scope in any way, and that there are other equally effective embodiments.

FIG. 1 illustrates a block diagram of an automated testing system, according to various embodiments;

FIG. 2 shows a conceptual diagram of preprocessing operations performed on test data prior to testing of a DUT, according to various embodiments;

FIG. 3 shows a conceptual diagram of the operations of a fine-grained control/feedback loop for controlling environmental test conditions, according to various embodiments;

FIG. 4 shows a conceptual graph illustrating an automated regulating of activity level of a DUT for maintaining a correct environmental test condition, according to various embodiments;

FIG. 5 shows a conceptual diagram of a switch system, according to various embodiments;

FIG. 6 is a flow diagram of method steps for preprocessing testing data, according to various embodiments; and

FIG. 7 is a flow diagram of method steps for maintaining correct environmental test conditions during testing of a DUT, according to various embodiments.

### DETAILED DESCRIPTION

In the following description, numerous specific details are set forth to provide a more thorough understanding of the various embodiments. However, it will be apparent to one skilled in the art that the inventive concepts may be practiced without one or more of these specific details.

An automated testing system for a DUT is disclosed herein that provides real-time and/or fine-grained adjustments for an activity level of the DUT to ensure the correct/target environmental test conditions are maintained during the entire testing period. The correct/target environmental test conditions can be specified via one or more environmental targets and ranges. The one or more environmental targets and ranges can define targets and ranges for any type of environmental condition/parameter, such as a target temperature and temperature range, a target voltage and voltage range, a target current and current range, a target power and power range, and the like. The testing system includes a set of sensors that generate a set of environmental data comprising one or more different types of environmental data, such as temperature data, voltage data, current data, power data, and the like. The testing system can determine the current environmental test conditions based on the set of environmental data.

The testing system also implements a real time and/or fine-grained control/feedback loop that, during the testing period, continuously determines if the actual/current environmental test conditions are in compliance with the correct environmental test conditions. If the testing system determines that the current environmental test conditions are not compliant with the correct environmental test conditions, the testing system determines one or more activity-modification techniques to be executed that advance/progress the actual environmental test conditions to be in compliance with the correct environmental test conditions. The one or more activity-modification techniques can increase or decrease the current activity level of the DUT. In general, applying an activity-modification technique can increase or decrease the workload, power duty cycle, and/or rate of testing of the DUT 150, which in turn will change the current activity level of the DUT 150. The activity level of the DUT is highly correlated with the environmental test conditions, whereby a change in the activity level of the DUT can directly and/or indirectly cause a corresponding change in the environmental test conditions.

The one or more activity-modification techniques can include, for example, inserting a throttling interval and/or directly regulating/adjusting one or more control parameters of the DUT, such as clock frequency, voltage, current, power, and the like. An activity-modification technique that decreases the activity level of the DUT is sometimes referred to as a throttling technique. An activity-modification technique that increases the activity level of the DUT is sometimes referred to as a negative throttling technique. If the fine-grained control/feedback loop determines that an activity-modification technique is needed, the fine-grained control loop also determines the amount/extent of each activity-modification technique that is to be executed, such as a specific number of wait cycles in the throttling interval or a specific adjustment value for a control parameter of the DUT, such as a specific adjustment value for the clock frequency, voltage, current, power, and the like.

The amount/extent of each activity-modification technique to be applied is determined based on the amount of difference/delta between the current environmental test conditions and the correct environmental test conditions. In some embodiments, the amount of each activity-modification technique can also be determined based on one or more modification factors that can each increase or decrease the amount of an activity-modification technique that is determined based on the amount of difference/delta alone. The computed amount of each activity-modification technique is then executed to either decrease (throttle) the activity level of the DUT or increase (negative throttle) the activity level of the DUT.

In some embodiments, a modification factor is the intensity level of a current block of test data. In these embodiments, the amount of each activity-modification technique can also be determined based on an intensity level associated with the current block of test data. The intensity level of a current block of test data is correlated with and reflects the amount of resources required by the DUT to execute the current block of test data. The resources required by the DUT to execute a block of test data can include computing resources and/or general resources, such as temperature budget, power budget, and the like.

For example, if the current block of test data has a relatively high intensity level, the amount of the activity-modification technique can be adjusted upwards to decrease the activity level of the DUT by a greater amount. In some embodiments, a modification factor is the intensity level of at least one future block of test data that is subsequent to the current block of test data. In these embodiments, the amount of an activity-modification technique can be determined further based on the intensity level associated with the at least one future block of test data which indicates the relative amount of computing resources of the DUT that will be required in the near future when executing the at least one future block of test data. For example, if the at least one future/subsequent block of test data has a relatively high intensity level, the amount of the activity-modification technique can be adjusted upwards to pre-emptively decrease the activity level of the DUT by a greater amount in anticipation of executing the future/subsequent block of test data having the relatively high intensity level. In other embodiments, the amount/extent of each activity-modification technique can further be determined based on other modification factors including the characteristics of the particular DUT, the testing system, and/or the testing environment.

To illustrate, the fine-grained control loop can continuously determine if the current temperature is approximately equal to a specified target temperature. If not, the fine-grained control loop can determine the amount of difference/delta between the current temperature and the target temperature, and determine an amount/extent of one or more activity-modification techniques to be applied based on the amount of difference/delta and one or more modification factors.

In some embodiments, the extent of an activity-modification technique can also be based on one or more predictive factors. In these embodiments, one or more predictive environmental trends can be identified from the set of environmental data used to determine the current environmental test conditions. The one or more predictive environmental trends can then be used to determine the amount of difference/delta between the current environmental test conditions and the correct environmental test conditions. For example, a predictive trend that the temperature is rising rapidly can be identified from the set of environmental data, whereby the predictive trend can be used to adjust upwards the computed amount of difference/delta between the current environmental test conditions and the correct environmental test conditions. The resulting adjusted increase in the amount of difference/delta can thereby increase the amount of the activity-modification technique (such as increasing the number of wait cycles in a throttling interval) to pre-emptively decrease the activity level of the DUT by a greater amount in anticipation of the rapidly rising temperature.

The testing system then executes the one or more activity-modification techniques to help bring the current environmental test conditions within the correct environmental test conditions. Overall, the testing system continuously monitors the current environmental test conditions via a set of sensors, determines any difference/delta between the current environmental test conditions and the correct environmental test conditions, determines and amount of one or more activity-modification techniques to be applied based on the computed difference/delta, various modification factors, and/or various predictive factors, and executes the one or more activity-modification techniques that adjust the activity level of the DUT to advance/progress the current environmental test conditions to be in compliance with the correct environmental test conditions. In this manner, the adjustments to the activity level of the DUT can be made continuously and in real-time to ensure that the correct environmental test conditions are maintained during the entire testing period.

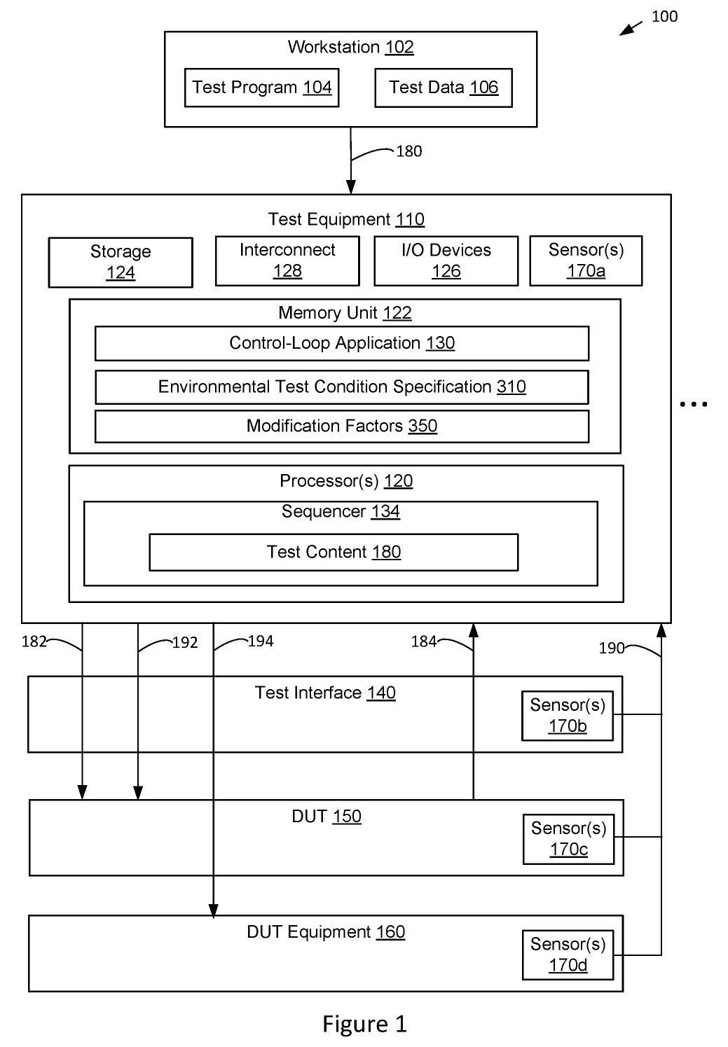

FIG. 1 illustrates a block diagram of an automated testing system 100, according to various embodiments. As shown, testing system 100 includes, without limitation, a workstation 102, a test equipment 110, a test interface 140, a device under test (DUT) 150, DUT equipment 160, and various sets of sensors 170 (such as 170a, 170b, 170c, and 170d). Test equipment 110 includes, without limitation, one or more processors 120, a memory unit 122, a storage 124, an I/O device interface 126, a set of sensors 170a, and an interconnect 128. In some embodiments, the testing system 100 can include multiple instances of the test equipment 110, each instance comprising one or more of a processor 120, memory unit 122, storage 124, I/O device interface 126, a set of sensors 170a, and/or interconnect 128. In these embodiments, the testing system 100 can include multiple instances of the test equipment 110 that operate in conjunction and in synchronization to perform the embodiments herein.

The workstation 102 comprises a computing device, such as a desktop computer, a laptop computer, a smart phone, a personal digital assistant (PDA), tablet computer, or any other type of computing device configured to receive input, process data, and optionally display images, and is suitable for practicing one or more embodiments. The workstation 102 includes a memory (not shown) and a processor (not shown). The memory of the workstation 102 can be similar to the memory unit of the testing equipment 110 and the processor of the workstation 102 can be similar to the processor of the testing equipment 110 which are described in detail below. The workstation 102 stores and compiles a test program 104 and test data 106 that are typically received from a customer, such as an entity that desires testing of the DUT 150. The workstation 102 can also preprocess the test data 106 to generate block metadata for the test data 106 if not already precomputed on another computing system prior to application on a physically different set of test systems.

Testing equipment 110 can comprise a computing device, such as a desktop computer, a laptop computer, a smart phone, a personal digital assistant (PDA), tablet computer, or any other type of computing device configured to receive input, process data, and optionally display images, and is suitable for practicing one or more embodiments. Testing equipment 110 described herein is illustrative and any other technically feasible configurations that fall within the scope of the present disclosure. In some embodiments, the testing system 100 can include multiple instances of the test equipment 110 that operate in conjunction and in synchronization to perform the embodiments herein.

Processor(s) 120 includes any suitable processor implemented as a central processing unit (CPU), a graphics processing unit (GPU), an application-specific integrated circuit (ASIC), a field programmable gate array (FPGA), an artificial intelligence (AI) accelerator, any other type of processor, or a combination of different processors, such as a CPU configured to operate in conjunction with a GPU. In general, processor(s) 120 may be any technically feasible hardware unit capable of processing data and/or executing software applications. Further, in the context of this disclosure, the computing elements shown in testing equipment 110 may correspond to a physical computing system (e.g., a system in proximity to the DUT) or may be a virtual computing instance executing within, for example, a computing cloud. In some embodiments, the processor 120 includes a sequencer 134 comprising a specialized instruction and/or test data storage.

Memory unit 122 includes a random access memory (RAM) module, a flash memory unit, or any other type of memory unit or combination thereof. Processor(s) 120 and I/O device interface 126 are configured to read data from and write data to memory unit 122. Memory unit 122 includes various software programs that can be executed by processor(s) 120 and application data associated with said software programs. In some embodiments, the memory unit 122 stores a control-loop and/or branching application 130, an environmental test condition specification 310, and modification factors 350.

Storage 124 includes volatile or non-volatile storage for applications and data, and may include fixed or removable disk drives, flash memory devices, and CD-ROM, DVD-ROM, Blu-Ray, HD-DVD, or other magnetic, optical, or solid state storage devices and/or memories. The storage 124 may be a disk drive storage device. Although shown as a single unit, the storage 124 may be a combination of fixed and/or removable storage devices, such as fixed disc drives, floppy disc drives, tape drives, removable memory cards, or optical storage, network attached storage (NAS), or a storage area-network (SAN). Software programs/applications and data may be stored in storage 124 and loaded into memory unit 122 when executed, such as the control-loop application 130, the environmental test condition specification 310, and the modification factors 350.

I/O device interface 126 enables communication of I/O devices with processor(s) 120. I/O device interface 126 generally includes the requisite logic for interpreting addresses corresponding to I/O devices that are generated by processor(s) 120. I/O device interface 126 may be implemented as any technically feasible CPU, ASIC, FPGA, any other type of processing unit or device. I/O devices include devices capable of providing input, such as a keyboard, a mouse, a touch-sensitive screen, a microphone, a remote control, a camera, and so forth, as well as devices capable of providing output, such as a display device. Additionally, I/O devices may include devices capable of both receiving input and providing output, such as a touchscreen, a universal serial bus (USB) port, and so forth. I/O devices may be configured to receive various types of input from an end-user of testing equipment 110, the workstation 102, and/or other instances of the test equipment 110 that operates in conjunction and in synchronization to perform the embodiments herein. I/O devices may also be configured to provide various types of output to the end-user of testing equipment 110, the workstation 102, and/or other instances of the test equipment 110, such as displayed digital images or digital videos or text or encoded results or measurements directly or indirectly received from the DUT 150.

The interconnect 128 is inclusive of any technically feasible internal and/or external data busses, memory busses, system busses, expansion busses and/or the like. The interconnect 128 includes a collection of electrical pathways that allows data, addresses, and control signals to be transferred between the various components of the testing equipment 110 and/or external devices and components. While discussed in the singular for clarity, the interconnect 128 is illustrative of one or more interconnects 128 that interconnect, for example, the processor 120, the memory unit 122, the I/O device interface 126, the storage 124, and a first set of sensors 170a. In some embodiments, the interconnect 128 incudes PCI Express (PCIe) connections for high-speed internal connections and Universal Serial Bus (USB) connections for connecting external devices.

The testing equipment 110 is configured to use the test interface 140 to send and receive signals to and from the DUT 150 and/or DUT equipment 160. The test interface 140 couples the testing equipment 110 to the DUT 150. The test interface 140 can be any technically feasible interface, such as a probe device, probe card, probe heads, load board, and/or the like. The test interface 140 includes a plurality of probes (not shown) that electrically couple the testing equipment 110 to contact points on the DUT 150. The test interface 140 allows test signals (input signals) to be transmitted from the testing equipment 110 to the DUT 150 and test results (output signals) from the DUT 150 to the testing equipment 110. The test interface 140 also proves an interface between the testing equipment 110 and the DUT equipment. In operation at testing, the testing equipment 110 controls the positioning of the test interface 140 relative to the DUT 150 so that one or more of the probes of the test interface 140 are placed into contact with corresponding contact points on the DUT 150.

The DUT 150 can comprise any type of semiconductor device, packaged integrated circuit (IC) device, chip, electronic printed board assembly that includes one or more electrical and/or electronic components, and/or the like. Note that different DUTs 150 can have different characteristics, such as different operating and/or electrical properties, when processing or executing the same block of test data, such as different temperatures, clock frequencies, voltages, power, and the like.

The DUT equipment 160 comprises device handling and cooling equipment for the DUT 150. The DUT equipment 160 can include one or more chucks or fixtures for holding the DUT 150 during the testing. The DUT equipment 160 can further include various cooling apparatus, such as fans, liquid cooling devices, active cooling devices, and/or the like to help control the temperature and/or other environmental test conditions of the DUT 150 during testing.

The various sets of sensors 170 can include different types of sensors that generate/collect different types of environmental data, such as temperature data, voltage data, power data, humidity, and the like. In other embodiments, the sets of sensors 170 can include any type of sensor that generates/collects any type of environmental data. As such, the sets of sensors 170 generate a set of environmental data comprising one or more different types of environmental data. The testing system 100 can determine the current environmental test conditions based on the set of environmental data. The various sets of sensors 170 (such as 170a, 170b, 170c, and 170d) can be placed in various locations on the testing system 100. For example, a first set of sensors 170a can be placed in various locations on the test equipment 110, a second set of sensors 170b can be placed in various locations on the test interface 140, a third set of sensors 170c can be placed in various locations on the DUT 150, and a fourth set of sensors 170d can be placed in various locations on the DUT equipment 160. For example, the third set of sensors 170c placed in various locations on the DUT 150 can include a temperature sensor that generates temperature data, a voltage sensor that generates voltage data, and a power sensor that generates power data.

As discussed above, the workstation 102 stores a test program 104 and test data 106. In some embodiments, the test program 104 and test data 106 are typically received from a customer, while in other embodiments the test program 104 and test data 106 originate from a different source. Together the test program 104 and test data 106 specify a “test” of the DUT 150 that can evaluate the accuracy and/or performance level of the DUT 150. In particular, together the test program 104 and test data 106 specify the test signals to be input to the DUT 150 during testing, and the test results that should be output by the DUT 150 for passing the test of the DUT 150.

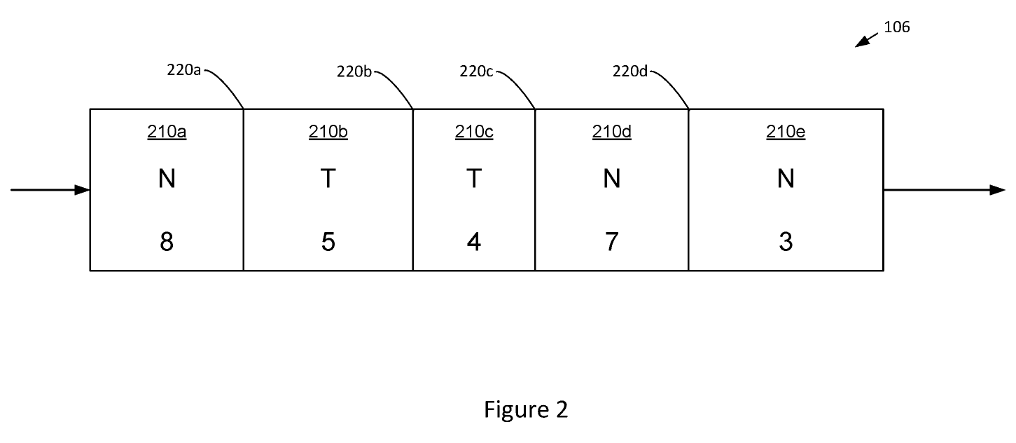

Prior to testing the DUT 150, the workstation 102 can perform preprocessing operations on the test data 106 to determine separate blocks of the test data 106, determine throttling/non-throttling blocks, and compute an intensity level for each block. The preprocessing operations on the test data 106 generate block metadata for the test data 106 that specify the separate blocks, the throttling/non-throttling blocks, and the intensity level for each block. Thus, the preprocessing operations can define the test data 106 as piecewise-linear content comprising a series of predefined blocks for piecewise-linear execution. The preprocessing operations on the test data 106 are discussed below in relation to FIG. 2.

During runtime when the DUT 150 is being tested, the workstation 102 compiles the test program 104 and test data 106 to generate test content 180 if needed. The test content 180 comprises a compiled and/or derived version of the test program 104 and test data 106 and is a, potentially partial, representation of the test program 104 and test data 106. The test content 180 will also comprise piecewise-linear content and include the block metadata generated for the test data 106 that specify the separate blocks, the throttling/non-throttling blocks, and the intensity level for each block or a selected set of blocks. As shown, the test content 180 is transmitted to the test equipment 110, which is stored in the sequencer 134 (processor cache) of the processor 120. The test content 180 represents the test data 106 and is sometimes referred to herein simply as test data 106. As such, the sequencer 134 comprises a pipeline of test data 106/test content 180 which stores zero, one or more blocks of test data 106/test content 180 at any given time. The workstation 102 can compile the test program 104 and test data 106 in a piece-wise fashion to generate enough test data 106/test content 180 to fill the sequencer 134. In other embodiments, the workstation 102 can compile the test program 104 and test data 106 all at once, whereby the entire test content 180 is stored to the memory unit 122 of the test equipment 110. The test data 106/test content 180 is then transferred to the sequencer 134 in a piecemeal fashion to fill the sequencer 134.

The processor 120 then processes the test data 106/test content 180 stored in the sequencer 134 to generate a series of test signals 182 that are input/transmitted to the DUT 150 via the test interface 140. The series of test signals 182 represent at least a portion of the test data 106 and the test content 180. The series of test signals 182 are then executed by the DUT 150 which outputs/generates a series of test results 184 (output signals) based on the series of test signals 182. The test results 184 are transmitted back to the processor 120 via the test interface 140, and the processor 120 analyzes the test results 184 to evaluate the accuracy and/or performance level of the DUT 150. For example, the processor 120 can determine whether the test results 184 remain within an acceptable range of values to determine if the DUT 150 has passed the testing and is operating properly.

During the period of testing of the DUT 150, the processor 120 executes the control-loop application 130 based, at least in part, on the environmental test condition specification 310 and the modification factors 350. The environmental test condition specification 310 can include specifications for the correct/target environmental test conditions that reflect the expected real-world operating conditions for the DUT 150. The control-loop application 130 implements a fine-grained control loop that, during the testing period, continuously monitors the current environmental test conditions, determines any difference/delta between the current environmental test conditions and the correct environmental test conditions, determines and amount of one or more activity-modification techniques to be applied based on the computed difference/delta, various modification factors, and/or various predictive factors, and executes the one or more activity-modification techniques that adjust the activity level of the DUT to advance/progress the current environmental test conditions to be in compliance with the correct environmental test conditions. In this manner, the adjustments to the activity level of the DUT can be made continuously and in real-time to ensure that the correct environmental test conditions are maintained during the entire testing period.

The current environmental test conditions can be determined by analyzing a set of environmental data 190 received from the sets of sensors 170. The correct environmental test conditions can be defined via one or more environmental targets and ranges that can be received from a user/customer and stored as the environmental test condition specification 310. In some embodiments, the one or more activity-modification techniques can include inserting a throttling interval in the test data 106/test content 180, such as inserting the throttling interval in the sequencer 134 that stores the test data 106/test content 180. In some embodiments, the one or more activity-modification techniques can include directly regulating/adjusting one or more control parameters of the DUT 150 via control signals 192 and or embedded into the test signals 182 that are transmitted to the DUT 150 via the test interface 140. The control signals 192 can adjust, for example, the clock frequency, voltage, and/or power for the DUT 150. In some embodiments, the one or more activity-modification techniques can include adjusting the parameters of the cooling apparatus of the DUT equipment 160 via adjustment signals 194 that are transmitted to the DUT equipment 160 via the test interface 140.

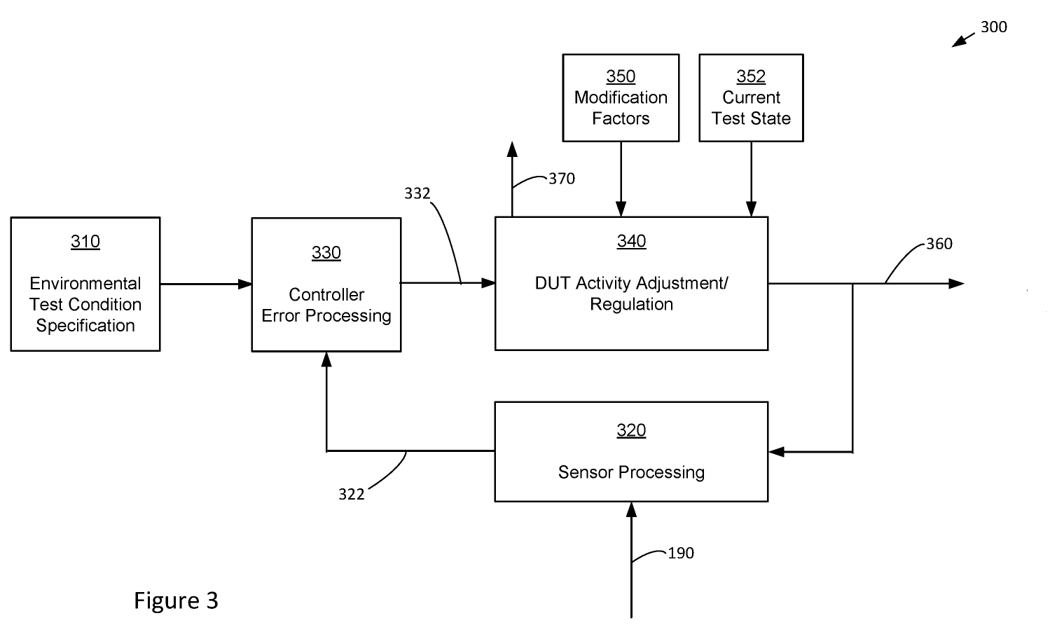

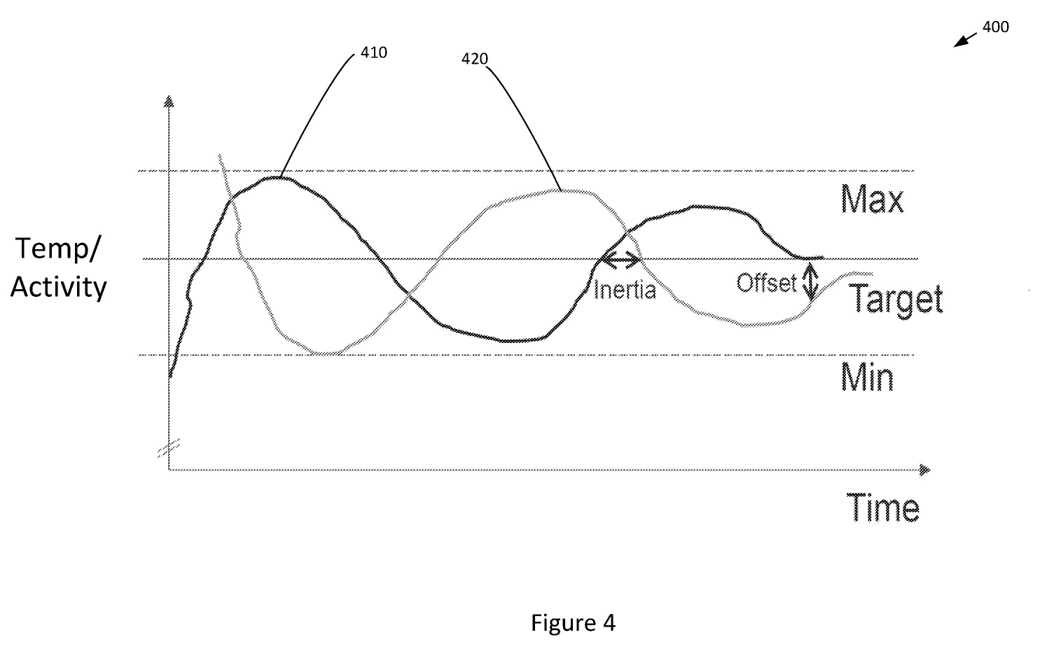

In other embodiments, the fine-grained control loop is not implemented by the control-loop application 130 but is implemented (partially or in whole) in hardware configured to perform the embodiments and techniques described herein. Advantageously, the hardware implementation can have less latency than the software implementation via the control-loop application 130. In these embodiments, the test equipment 110 can include a set of electrical circuits and components configured to execute the functions and operations of the fine-grained control loop described herein. For example, the set of electrical circuits and components can include dedicated hardware-acceleration elements such as FPGAs, microcontrollers, ASICs, and the like. The functions and operations of the fine-grained control loop are discussed below in relation to FIGS. 3-4.

As discussed above, prior to testing the DUT 150, the workstation 102 can perform preprocessing operations on the test data 106 to determine separate blocks of the test data 106, determine throttling/non-throttling blocks, and compute an intensity level for each block. FIG. 2 shows a conceptual diagram of preprocessing operations performed on test data prior to testing of a DUT, according to various embodiments.

The preprocessing operations include dividing the test data 106 into a series of separate predefined blocks 210 (such as 210a, 210b, 210c, etc.) configured for piecewise-linear execution. A series of breakpoints 220 (such as 220a, 220b, 220c, etc.) separate and divide the test data 106 into the series of blocks 210. As such, a breakpoint 220 comprises a location in the test data 106 where the test data 106 is divided into two separate blocks 210. In general, a block 210 comprises a set of related test data 106. In some embodiments, there is no predefined data size for the blocks 210, whereby the amount of test data 106 included in each block 210 can vary from one block to another. The preprocessing operations can also associate block metadata with each block 210 that defines the block, such as specifying a beginning and end of the block 210.

The workstation 102 can separate the test data 106 into the series of blocks 210 by determining where to insert breakpoints 220 in the test data 106. As discussed above, the combination of the test program 104 and test data 106 specify the “test” for the DUT 150. Before inserting a particular breakpoint 220 in the test data 106 to generate two separate blocks 210, the workstation 102 first determines that the integrity of the “test” is not violated (the functionality of the test is not changed) such that the test results from the execution of the test will still be valid and the test can still test for the correct functionality of the DUT 150 if the particular breakpoint 220 is inserted in the test data 106. If the integrity of the test will not be violated, the particular breakpoint 220 can be inserted in the test data 106 to generate the two separate blocks 210. In addition, each resulting block 210 is atomic, whereby no additional breakpoints 220 can be inserted within the block 210 without violating the integrity of the test and changing the functionality of the test.

The preprocessing operations also include identifying whether each block in the series of blocks is a throttling block or a non-throttling block. A throttling block comprises a block 210 of test data 106 where one or more activity-modification techniques are permitted to be performed during execution of the fine-grained control loop. In particular, when a throttling block is currently being processed by the fine-grained control loop, the fine-grained control loop is permitted to implement one or more activity-modification techniques. A non-throttling block comprises a block 210 of test data 106 where an activity-modification technique is not permitted to be performed during execution of the fine-grained control loop. In particular, when a non-throttling block is currently being processed by the fine-grained control loop, the fine-grained control loop is not permitted to implement any activity-modification techniques. Each block 210 is then marked/labeled as either a throttling block (as indicated by “T”) or a non-throttling block (as indicated by “N”). The preprocessing operations can associate block metadata with each block 210 that also specifies the throttling/non-throttling label for the block 210.

The workstation 102 can identify a particular block 210 as a throttling block if performing one or more activity-modification techniques during execution of the particular block 210 does not violate the integrity of the test of the DUT 150 (the functionality of the test is not changed) such that the test results will still be valid, the functionality of the DUT 150 is still properly tested, the relevant timing and performance aspects of the test are not affected, and/or there is no impact (or tolerable impact) to the test results. Any blocks 210 not identified as a throttling block can be identified as a non-throttling block. A non-throttling block includes a set of test data 106 whereby execution of the set of test data 106 that must be executed from beginning to end without interruption from performing any activity-modification technique. For example, when a particular block 210 includes a set of test data 106 that is testing the timing or performance of the DUT 150 where execution of the particular block 210 cannot be interrupted or modified without affecting the timing or performance of the DUT 150, the particular block 210 would be identified as a non-throttling block.

The preprocessing operations further can include computing, for each block 210 in the series of blocks, an intensity level for the block 210. Each block 210 is then associated with the intensity level computed for the block 210, as indicated by the numerical values, such as “8,” “5,” “4,” etc. The preprocessing operations can associate block metadata with each block 210 that further specifies the computed intensity level for the block 210. The intensity level associated with a block 210 is determined based on the test data 106 contained within the block 210. The intensity level of a block 210 is highly correlated with and reflects/indicates the amount of resources that the DUT 150 will consume when executing the test data 106 of the block 210. The resources consumed by the DUT to execute a block 210 of test data 106 can include computing resources (such as memory and processing resources) and/or general resources, such as energy consumption.

Thus, the intensity level of a block 210 is highly correlated with and reflects/indicates the amount of computing resources of the DUT 150 required to execute the block 210, whereby a higher intensity level indicates that a greater amount of resources are consumed and a lower intensity level indicates that a lesser amount of resources are consumed. The intensity levels can also be normalized to a predetermined scale, such as from levels 1 to 10. Note that the amount of computing resources of the DUT 150 that are consumed within a given time period is also highly correlated with the temperature, voltage, and power of the DUT 150, whereby a greater amount of resources being consumed will correlate to a higher temperature, and/or and energy consumption of the DUT 150. As such, the intensity level of a block 210 is also highly correlated with and reflects/indicates the temperature, voltage, and power of the DUT 150, whereby a higher intensity level will correlate to a higher temperature, voltage, and power of the DUT 150. In another embodiment, the intensity level and can also be anti-correlated or show any other form of more generalized form of correlation.

During runtime when the DUT 150 is being tested, the workstation 102 compiles the test program 104 and test data 106 to generate test content 180. The test content 180 represents the test data 106 and thus will also comprise piecewise-linear content and be divided into a series of blocks 210. In addition, the test content 180 will include the block metadata generated for the test data 106 that specify the separate blocks 210, the throttling/non-throttling blocks 210, and the intensity level for each block 210. The test content 180 represents the test data 106 and is sometimes referred to herein simply as test data 106.

During the period of testing of the DUT 150, the test equipment 110 executes the test program 104 and test data 106 (as represented by the test content 180 and test signals 182). While testing the DUT 150, the test equipment 110 also continuously executes the control-loop application 130 throughout the duration of the test. The control-loop application 130 implements a fine-grained control/feedback loop that ensures the correct environmental test conditions are maintained throughout the testing period. In other embodiments, the fine-grained control loop is not implemented by the control-loop application 130 but is implemented (partially or in whole) in hardware. FIG. 3 shows a conceptual diagram of the operations of a fine-grained control/feedback loop for controlling environmental test conditions, according to various embodiments. As shown, the fine-grained control loop 300 is illustrated as a set of function blocks representing an environmental test condition specification 310, sensor processing 320, controller error processing 330, and DUT activity adjustment/regulation 340. Each function block 310, 320, 330, and 340 can represent a set of functions and operations performed by the function block and can be implemented in hardware as a set of circuit components/modules that execute the set of functions and operations of the function block.

The environmental test condition specification 310 comprises a specification for the correct/target environmental test conditions, which can be defined via one or more environmental targets and ranges. The one or more environmental targets and ranges can define targets and ranges for any type of environmental condition/parameter, such as a target temperature and temperature range, a target voltage and voltage range, a target power and power range, and the like. A target environment value for a particular environmental condition/parameter indicates that the fine-grained control loop 300 should attempt to maintain the target environment value for the particular environmental condition/parameter during the testing of the DUT 150, such as maintaining the DUT temperature, voltage, and/or power at the target environment value. A range of values for a particular environmental condition/parameter indicates that when the particular environmental condition/parameter goes outside the range of values during the testing of the DUT 150, an alarm process 370 can be triggered. Note that the correct/target environmental test conditions can be defined by a plurality of different environmental targets and ranges, depending on the needs of the customer. An example of a correct environmental test condition being defined as a target temperature and temperature range is discussed below in relation to FIG. 4.

The sensor processing 320 receives a set of environmental data 190 that are received from the sets of sensors 170 placed at various locations throughout the testing system 100, such as the test equipment 110, the test interface 140, the DUT 150, and/or the DUT equipment 160. The set of environmental data 190 can include one or more different types of environmental data, such as temperature data, voltage data, power data, and the like. In general, the set of environmental data 190 will include the one or more types of environmental data corresponding to the one or more types of environmental conditions/parameters that are used to define the correct/target environmental test conditions in the specification 310.

For each particular type of environmental data, the sensor processing 320 analyzes the set of environmental data 190 to determine a current environment value 322 that represents the particular type of environmental data. In some embodiments, the current environment value 322 comprises a single numerical value that represents the particular type of environmental data. For example, for temperature data, the sensor processing 320 analyzes the temperature data in the set of environmental data 190 to determine a current environment value 322 that represents the temperature data. In some embodiments, although the temperature data can originate from a plurality of sensors 170 placed at a plurality of locations on the testing system 100, the sensor processing 320 can compute a single value (current environment value 322) that represents all the temperature data. In some embodiments, temperature data originating from different locations can have different weights, such as a greater weight being assigned to temperature data originating from the DUT 150. Likewise for voltage data, the sensor processing 320 analyzes the voltage data in the set of environmental data 190 to determine a current environment value 322 that represents the voltage data, and so forth for the other different possible types of environmental data.

In some embodiments, the sensor processing 320 analyzes past and current sets of environmental data 190 to determine one or more predictive environmental trends that can be used to adjust upwards to downwards the current environment value 322. For example, a predictive trend that the temperature is rising rapidly can be identified from the set of environmental data 190, whereby the predictive trend can be used to adjust upwards the current environment value 322. The resulting adjusted increase in the current environment value 322 can thereby increase the amount of the activity-modification technique (such as increasing the number of wait cycles in a throttling interval) to pre-emptively decrease the activity level of the DUT 150 by a greater amount in anticipation of the rapidly rising temperature. The sensor processing 320 can implement various techniques to analyze the past and current sets of environmental data 190 to identify the predictive environmental trends, such as geometric analysis, time-series analysis, extrapolation, or neural network-based predictive methods and/or a combination thereof. In these embodiments, the amount/extent of an activity-modification technique can be based on one or more predictive factors.

The controller error processing 330 receives as input the environmental test condition specification 310 and the current environment value 322 and computes and outputs a current delta value 332. In particular, the environmental test condition specification 310 specifies at least one target environment value for a particular environmental condition/parameter and the current environment value 322 comprises a single value representing the current value for the particular environmental condition/parameter. The current delta value 332 is then determined by computing the difference between the current environment value 322 and the target environment value. As such, if the current environment value 322 is higher than the target environment value, the current delta value 332 comprises a positive value, whereas if the current environment value 322 is lower than the target environment value, the current delta value 332 comprises a negative value. In other embodiments, depending on the particular environmental test condition, an inverse case is also possible whereby if the current environment value 322 is higher than the target environment value, the current delta value 332 comprises a negative value, whereas if the current environment value 322 is lower than the target environment value, the current delta value 332 comprises a positive value.

The DUT activity adjustment 340 collects/receives as input the current delta value 332, the modification factors 350, and a current test state 352, and outputs a set of one or more executable activity-modification techniques 360 (including an amount for each activity-modification technique). In particular, the DUT activity adjustment 340 first determines whether to proceed with further analysis based on the current test state 352, if so then determines an initial amount of each activity-modification technique based on the current delta value 332, and then can modify (increase or decrease) the initial amount of each activity-modification technique based on one or more of the modification factors 350 to generate a final amount of each activity-modification technique. The final amount of each activity-modification technique is then included in the set of executable activity-modification techniques 360 which output by the DUT activity adjustment 340 and executed by the test equipment 110.

First, the DUT activity adjustment 340 determines whether to proceed with further analysis based on the current test state 352. The current test state 352 can be a throttling block 210, non-throttling block 210, or a breakpoint 220 and well other test content such as already executed test results and its environmental conditions. The current test state 352 is determined by analyzing the block metadata of the test data 106/test content 180 currently stored in the sequencer 134, which can store one or more blocks 210 of test data 106/test content 180 as well as breakpoints 220 between the blocks 210. The DUT activity adjustment 340 determines what current element of the test data 106/test content 180 stored in the sequencer 134 is currently being processed and executed for testing the DUT 150, the current element being a throttling block 210, a non-throttling block 210, or a breakpoint 220. In some embodiments, an activity-modification technique can only be performed when the current element is a throttling block 210 or a breakpoint 220 and cannot be performed when the current element is a non-throttling block 210. Thus, the DUT activity adjustment 340 determines to proceed with further analysis if the current element is a throttling block 210 or a breakpoint 220 and determines not to proceed with further analysis if the current element is a throttling block 210, in which case the current iteration of the fine-grained control loop 300 ends.

If the DUT activity adjustment 340 determines to proceed with further analysis, the DUT activity adjustment 340 then determines an initial amount of each activity-modification technique based on the current delta value 332. In some embodiments, to determine the initial amount for a particular activity-modification technique, the DUT activity adjustment 340 applies a predetermined mapping value to the current delta value 332. The predetermined mapping value is associated with the specific combination of the particular type of environmental condition/parameter represented by the current delta value 332 and the particular activity-modification technique. In these embodiments, a plurality of predetermined mapping values can be stored in memory unit 122, each predetermined mapping value corresponding to a different and unique combination of a particular type of environmental condition/parameter and a particular activity-modification technique.

For example, assume that the current delta value 332 indicates a current temperature value 322 that is positive 3 degrees higher than the target temperature value and the particular activity-modification technique comprises inserting a throttling interval. A particular predetermined mapping value stored for the unique combination of the temperature condition/parameter and the throttling interval technique can be retrieved from memory unit 122 and applied to the current delta value 332. For example, the particular predetermined mapping value can indicate that for every positive 1 degree of temperature delta, the inserted throttling interval contains X number of wait cycles or NOPs. Therefore, the DUT activity adjustment 340 can apply the particular predetermined mapping value to the current delta value 332 to determine that the throttling interval will contain 3X wait cycles or NOPs. As such, the initial amount of the particular activity-modification technique comprises inserting a throttling interval containing 3X wait cycles or NOPs.

As another example, assume that the current delta value 332 indicates a current temperature value 322 that is positive 3 degrees higher than the target temperature value and the particular activity-modification technique comprises adjusting (upwards or downwards) the current power for the DUT 150. A particular predetermined mapping value stored for the unique combination of the temperature condition/parameter and the DUT power control technique can be retrieved from memory unit 122 and applied to the current delta value 332. For example, the particular predetermined mapping value can indicate that for every positive 1 degree of temperature delta, the current power of the DUT is decreased by Y watts. Therefore, the DUT activity adjustment 340 can apply the particular predetermined mapping value to the current delta value 332 to determine that the current power of the DUT is to be decreased by 3Y watts. As such, the initial amount of the particular activity-modification technique comprises decreasing the DUT power by 3Y watts.

In these embodiments, any number of predetermined mapping values for any number of different combinations of a particular type of delta value 332 and a particular type of activity-modification technique can be stored and retrieved from memory unit 122. The different types of delta values 332 in these combinations can include, without limitation, delta values 332 associated with temperature, DUT clock frequency, DUT voltage, DUT power, and the like. The different types of activity-modification technique in these combinations can include, without limitation, inserting of a throttling interval or directly regulating/adjusting one or more control parameters of the DUT, such as clock frequency, voltage, power, and the like.

The DUT activity adjustment 340 can then modify (increase or decrease) the initial amount of each activity-modification technique based on one or more of the modification factors 350 to generate a final amount of each activity-modification technique. For example, the initial number of wait cycles/NOPs determined for an inserted throttling interval can be increased or decreased based on the one or more of the modification factors 350 to generate a final amount for this activity-modification technique. For example, the initial adjustment value determined for adjusting a particular control parameter of the DUT (such as clock frequency, voltage, power, etc.) can be increased or decreased based on the one or more of the modification factors 350 to generate a final amount for this activity-modification technique.

In some embodiments, a modification factor is the intensity level associated with a current block 210 in the sequencer 134 that is currently being executed for testing the DUT 150. The intensity level of the current block 210 can be identified from the block metadata associated with the block 210. Note that the intensity level of a current block 210 is correlated with and reflects the amount of resources required by the DUT 150 to execute the current block 210, which in turn is correlated with the activity level of the DUT 150 and the resulting environmental test conditions, which in turn is correlated with the amount/extent of activity-modification techniques that are applied. Thus, the intensity level of a current block 210 should be considered when determining the amount/extent of an activity-modification techniques to be applied. For example, if the current block of test data has a relatively high intensity level, the initial amount of the activity-modification technique can be adjusted upwards (increased) to cause a greater decrease in the activity level of the DUT relative to the initial amount of the activity-modification technique. As another example, if the current block of test data has a relatively low intensity level, the initial amount of the activity-modification technique can be adjusted downwards (decreased) to cause a lesser decrease in the activity level of the DUT relative to the initial amount of the activity-modification technique.

In some embodiments, a modification factor is the intensity level of at least one future block 210 that is subsequent to the current block 210 in the sequencer 134. For example, a future block 210 can be a next block 210 in the sequencer 134 relative to the current block 210 that is currently being executed for testing the DUT 150. The intensity level of the at least one future block 210 can be identified from the block metadata associated with the at least one future block 210. In these embodiments, the amount of an activity-modification technique can be determined further based on the intensity level associated with the at least one future block 210 which indicates the relative amount of resources of the DUT 150 that will be required in the near future when executing the at least one future block 210. For example, if the at least one future/subsequent block 210 has a relatively high intensity level, the initial amount of the activity-modification technique can be adjusted upwards (increased) to pre-emptively decrease the activity level of the DUT by a greater amount, relative to the initial amount of the activity-modification technique, in anticipation of executing the future block 210 having the relatively high intensity level.

In some embodiments, a modification factor is an identified trend relating to the delta value 332. In these embodiments, the DUT activity adjustment 340 can analyze previously received delta values 332 and the current delta value 332 to determine a trend in the change of the delta value 332, and modify the initial amount of each activity-modification technique based on an identified trend. For example, if the identified trend indicates that the temperature is rising rapidly based on the recent changes in the received delta values 332, the initial amount of the activity-modification technique can be adjusted upwards (increased) to pre-emptively decrease the activity level of the DUT by a greater amount, relative to the initial amount of the activity-modification technique, in anticipation of the rapidly rising increase in temperature.

In some embodiments, a modification factor comprises one or more characteristics of the DUT 150, the testing equipment 110, and/or the testing environment. The characteristics of the DUT 150 can include one or more electrical properties of the DUT 150 such as its specific power consumption, intrinsic resistances, leakage, minimal or maximal operating voltages or any other manufacturing related DUT properties. Note that the electrical properties of different DUTs 150 can vary, whereby different DUTs 150 can have different levels of efficiency and operate using different clock frequencies, voltages, and power levels. Therefore, the same amount of adjustment to a particular control parameter for two different DUTs 150 can impact the activity level of the DUTs 150 to a different extent. Thus, the characteristics of the DUT 150 should be considered when determining the amount/extent of an activity-modification techniques to be applied.

The characteristics of the testing system 100 can include one or more electrical properties of the test equipment 110 and/or the test interface 140 such as its specific signal accuracy, resistance, signal integrity, and/or thermal conductance.

The characteristics of the test environment can include one or more current environmental conditions of the testing environment, such as a current temperature of the test equipment 110, the test interface 140, and/or the DUT equipment 160, as detected via the sets of sensors 170 (such as 170a, 170b, and 170d). For example, if the current temperature of the test environment is relatively high, the initial amount of the activity-modification technique can be adjusted upwards (increased) to cause a greater decrease in the activity level of the DUT relative to the initial amount of the activity-modification technique. As another example, if the current temperature of the test environment is relatively low, the initial amount of the activity-modification technique can be adjusted downwards (decreased) to cause a lesser decrease in the activity level of the DUT relative to the initial amount of the activity-modification technique.

In other embodiments, the DUT activity adjustment 340 can implement another technique for determining the amount/extent for an activity-modification technique based on the current delta value 332. For example, the DUT activity adjustment 340 can implement a proportional integral derivative (PID) control regulation or other type of automated control regulation that is based on learned, derived or otherwise determined correlation factors between inputs (such as delta value 332) and outputs (such as throttling intervals and/or DUT control parameter values) to automatically adjust the outputs to reach a desired setpoint (such as a target temperature value where the delta value 332 equals 0). Such automated control regulation can automatically modulate between the input values and the output values to maintain the desired setpoint.

For each activity-modification technique to be implemented by the DUT activity adjustment 340, the final amount of each activity-modification technique is included in the set of executable activity-modification techniques 360 which is output by the DUT activity adjustment 340 and executed by the test equipment 110. In some embodiments, the set of executable activity-modification techniques 360 can include inserting a throttling interval having X wait cycles/NOPs. In these embodiments, the DUT activity adjustment 340 can insert/add the specified throttling interval into the sequencer 134 which stores the blocks 210 of test data 106/test content 180. In some embodiments, the set of executable activity-modification techniques 360 can include adjusting a control parameter of the DUT 150 (such as a clock frequency, voltage, power) by a specified adjustment amount. In these embodiments, the DUT activity adjustment 340 can directly adjust the control parameter of the DUT 150 by the specified adjustment amount via control signals 192 that are transmitted to the DUT 150 via the test interface 140.

In general, the DUT activity adjustment 340 can implement various activity-modification techniques that can insert a throttling interval and/or adjust any variety of control parameters for the DUT 150 via the control signals 192, including but not limited to, clock frequency, voltage supply, power supply, current, and disturbances (such as Jitter, Noise, Ripple), and the like. By inserting a throttling interval and/or changing the control parameters for the DUT 150, the workload, power duty cycle, and/or rate of testing of the DUT 150 can be changed, which in turn will change the current activity level of the DUT 150, which in turn will change the current environmental test conditions. For example, by inserting a throttling interval and/or reducing the clock frequency, voltage, and/or power of the DUT 150, the workload, power duty cycle, and/or rate of testing of the DUT 150 will be reduced, which in turn will reduce the current activity level of the DUT 150, which will reduce the temperature of the DUT 150 to advance the current temperature towards the target temperature within the temperature range. In some embodiments, the DUT activity adjustment 340 can further implement various activity-modification techniques that can adjust any variety of parameters for the DUT equipment 160 via the adjustment signals 194, including but not limited to, fan speed, rate of liquid cooling devices, rate of active cooling devices, and the like.

During testing of the DUT 150, an unusual situation can occur when a current environmental condition (such as current temperature) goes outside of an acceptable range of values for the environmental condition (such as a maximum acceptable temperature) as specified in the environmental test condition specification 310. If the DUT activity adjustment 340 detects such a situation, an alarm process 370 can be triggered whereby the testing of the DUT 150 is stopped or temporarily paused. The alarm process 370 can be triggered as a safety feature to prevent damage to the DUT 150, the test interface 140, the DUT equipment 160 and/or the testing system 100.

FIG. 4 shows a conceptual graph illustrating an automated regulating of activity level of a DUT for maintaining a correct environmental test condition, according to various embodiments. In the example of FIG. 4, the correct environmental test condition is defined as a target temperature and temperature range. However, in other embodiments, the correct environmental test condition can be defined based on a different type of environmental condition.

As shown, the graph 400 includes a first axis (vertical axis) representing the temperature and DUT activity level and a second axis (horizontal axis) representing time during the DUT testing. The graph 400 also includes a target temperature (setpoint) and a temperature maximum and minimum (temperature range). A first curve 410 indicates the fluctuations of the actual DUT temperature over time and a second curve 420 indicates the fluctuations of the DUT activity level over time. The fine-grain control/feedback loop is implemented to continuously adjust the activity level of the DUT to progress/advance the actual DUT temperature towards the target temperature. The resulting fluctuations of the first curve 410 and second curve 420 indicate that the actual DUT temperature is highly correlated with the DUT activity level. As shown, there is an inertia period between the adjustments to the activity level of the DUT and the resulting DUT temperature.

As shown, during the testing period, there are time periods where the activity level of the DUT 150 should be decreased, for example, by decreasing DUT power to reduce the current temperature towards the target temperature. However, during the testing period, there are also time periods where the activity level of the DUT 150 should be increased, for example, by increasing the DUT voltage, power, and/or clock frequency to increase the current temperature towards the target temperature. Note that it is also undesirable for the activity level of the DUT 150 and the temperature to be too low relative to the target temperature as this condition will reduce the overall speed of the testing, thus resulting in longer test times and less testing efficiency for the DUTs 150. Also, having the activity level of the DUT 150 and the testing temperature be too low relative to the target temperature will also give inaccurate test results (such as lower performance scores) as the DUT 150 is not being tested under real-world operating conditions as specified by the correct environmental test conditions.

In general, the current activity level of the DUT 150 is based, at least in part, on the intensity level of a current block 210 being executed by the DUT 150. As such, the activity level of the DUT 150 is highly correlated with the intensity level of a current block 210, and thus is also highly correlated with the amount of computing resources current being consumed by the DUT 150 to execute the current block 210. However, the intensity level of a block 210 can be determined before testing of the DUT 150 begins based on the test data 106 included in the block 210 during preprocessing of the test data 106. In contrast, the current activity level of the DUT 150 is determined during testing of the DUT 150 based on the intensity level of a current block 210 as well as current environmental test conditions that are only known when the actual testing occurs. This is due to the fact that each DUT 150, test equipment 110, and test interface 140 will have different electrical and efficiency behaviors/characteristics that will alter the environmental test conditions differently during testing. As such, even when executing the same block 210 of test data 106 having the same intensity level, different DUTs 150 will consume different amounts of resources and exhibit different activity levels. For example, the current environmental test conditions can affect/change the current activity level of the DUT 150 include current operating conditions of the DUT 150, such as the temperature, voltage applied, power consumption, average current delivery, clock frequency, workload, duty cycle, rate of testing, and/or the like. Other current environmental test conditions can affect/change the current activity level of the DUT 150 include, for example, the temperature of the test equipment 110 and/or the test interface 140.

As discussed above, the set of executable activity-modification techniques 360 can include inserting a throttling interval having X wait cycles/NOPs. In some embodiments, the DUT activity adjustment 340 can insert/add the specified throttling interval into the sequencer 134 which stores the blocks 210 of test data 106/test content 180. The DUT activity adjustment 340 can do so using conventional techniques by first clearing the sequencer 134 (cache pipeline) of the current blocks 210 of test data 106/test content 180, and then inserting the specified throttling interval into the sequencer 134. However, the conventional process of clearing the sequencer 134 and then inserting the specified throttling interval can incur significant latency.

In an alternative embodiment, a switch system is implemented to quickly switch between a first cache pipeline storing blocks 210 of test data 106/test content 180 and a second cache pipeline storing wait cycles/NOPs and/or other test content when inserting a throttling interval. In these embodiments, the switch system inserts a throttling interval in the test data 106/test content 180 via a switch that switches the testing of the DUT 150 between the test data 106/test content 180 and a series of wait or NOP cycles.

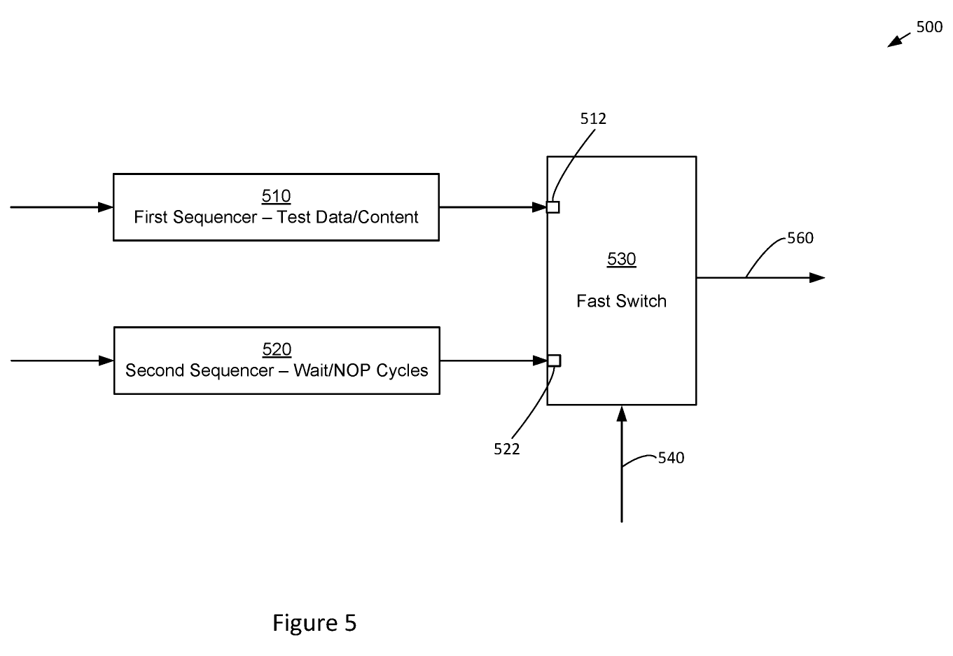

FIG. 5 shows a conceptual diagram of a switch system 500, according to various embodiments. As shown, the switch system 500 includes, without limitation, a first sequencer 510 (first cache pipeline), a second sequencer 520 (second cache pipeline), and a fast switch 530. A first input 512 of the fast switch 530 is coupled to the first sequencer 510 and a second input 522 of the fast switch 530 is coupled to the second sequencer 520. The fast switch 530 receives as input, at any given time, either the blocks 210 of test data 106/test content 180 from the first sequencer 510 (via the first input 512) or the wait cycles/NOPs from the second sequencer 520 (via the second input 522). The fast switch 530 also generates as output 560, at any given time, either the blocks 210 of test data 106/test content 180 from the first sequencer 510 or the wait cycles/NOPs from the second sequencer 520 depending on a switch control signal 540 received from the DUT activity adjustment 340. The value of the switch control signal 540 controls, at any given time, which input (either the blocks 210 from the first sequencer 510 or the wait cycles/NOPs from the second sequencer 520) the fast switch 530 receives and then generates as output 560 as a series of test signals 182 that are transmitted to the DUT 150 for execution via the test interface 140.

In these embodiments, during normal testing when no throttling intervals are to be inserted, the DUT activity adjustment 340 transmits a switch control signal 540 to the fast switch 530 to have the input switched to the first input 512 coupled to the first sequencer 510 as a default, which causes the fast switch 530 to transmit as output 560 the blocks 210 stored in the first sequencer 510. However, when the set of executable activity-modification techniques 360 includes inserting a throttling interval having X wait cycles/NOPs, the DUT activity adjustment 340 then transmits another switch control signal 540 to the fast switch 530 to switch the input to the second input 522 coupled to the second sequencer 520, which causes the fast switch 530 to transmit as output 560 the wait cycles/NOPs stored in the second sequencer 520. When X number of wait cycles/NOPs are finished being output (as a series of test signals 182 that are transmitted to the DUT 150), the DUT activity adjustment 340 then transmits another switch control signal 540 to the fast switch 530 to have the input switched back to the first input 512 coupled to the first sequencer 510, which causes the fast switch 530 to again transmit as output 560 the blocks 210 stored in the first sequencer 510 to resume the testing.

Implementing the switch system 500 when inserting throttling intervals can significantly reduce the latency relative to conventional techniques. In particular, when inserting a throttling interval, the switch system 500 does not require that the blocks 210 currently stored in the sequencer 134 be cleared, which incurs significant latency. In addition, the switch system 500 also does not require that the X wait cycles/NOPs then be inserted into the sequencer 134, which also incurs significant latency. Rather, in the switch system 500, a series of wait cycles/NOPs are pre-stored to the second sequencer 520 prior to the inserting of a throttling interval is needed by the DUT activity adjustment 340. In an additional embodiment, the switch system 500 is also used to process and/or react to the alarm process 370 with reduced latency.

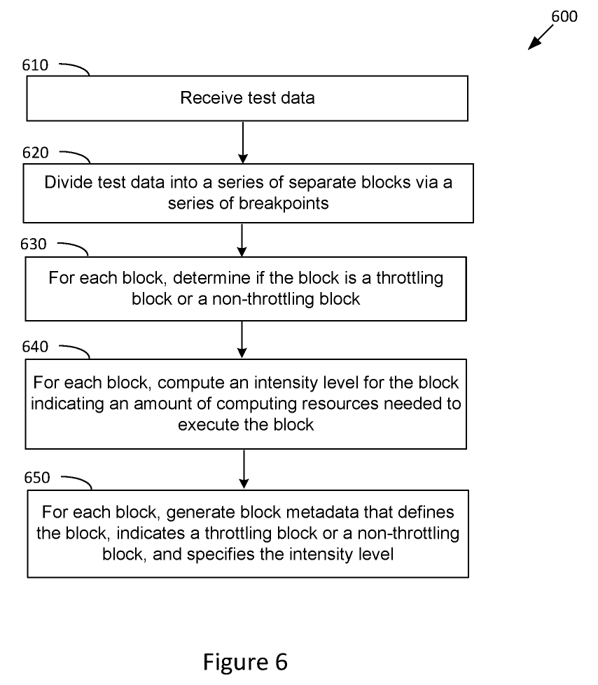

FIG. 6 is a flow diagram of method steps for preprocessing testing data 106, according to various embodiments. Although the method steps are described in conjunction with the embodiments of FIGS. 1-5, persons of ordinary skill in the art will understand that any system configured to perform the method steps, in any order, is within the scope of the invention. In some embodiments, the method 600 is performed by a workstation 102 coupled to a test equipment 110 that performs testing of the DUT 150. In other embodiments, the method 600 can be performed by the test equipment 110.

As shown, the method 600 begins at step 610, where the workstation 102 receives the test data 106. In some embodiments, the test data 106 is typically received from a customer, such as an entity that desires testing of the DUT 150. In other embodiments the test data 106 can originate from a different source.

At step 620, the workstation 102 divides the test data 106 into a series of separate blocks 210 configured for piecewise-linear execution. The workstation 102 determines a series of breakpoints 220 that divide the test data 106 into the series of blocks 210 such that the integrity of the test is not violated. The amount of test data 106 included in each block 210 can vary from one block to another.

At step 630, the workstation 102, for each block 210 in the series of blocks, determines if the block 210 is a throttling block or a non-throttling block. A throttling block comprises a block 210 where one or more activity-modification techniques are permitted to be performed during execution of the fine-grained control loop. A non-throttling block comprises a block 210 where an activity-modification technique is not permitted to be performed during execution of the fine-grained control loop. The workstation 102 can identify a particular block 210 as a throttling block if performing an activity-modification technique during execution of the particular block 210 does not violate the integrity of the test of the DUT 150 such that the test results will still be valid. Any block 210 not identified as a throttling block can be identified as a non-throttling block.

At step 640, the workstation 102, for each block 210 in the series of blocks, computes an intensity level for the block 210. The intensity level associated with a block 210 is determined based on the test data 106 contained within the block 210. The intensity level of a block 210 generally indicates the amount of resources that the DUT 150 will consume when executing the test data 106 of the block 210. In an additional embodiment, the intensity level of a block 210 can be based on (for example, averaged) multiple executions of the block 210 by the same DUT and/or at least one different DUT, on the same test interface 140 and/or at least one different test interface 140, on the same test equipment 110 and/or at least one different test equipment 110, on the same DUT equipment 160 and/or at least one different DUT equipment 160, or any combination thereof to increase the accuracy of the computed intensity level in the presence of variations or measurement inaccuracies.

At step 650, the workstation 102, for each block 210 in the series of blocks, generates and associates block metadata for the block 210 that defines the block 210, indicates whether the block 210 is a throttling block or a non-throttling block, and the intensity level computed for the block 210. The method 600 then ends.

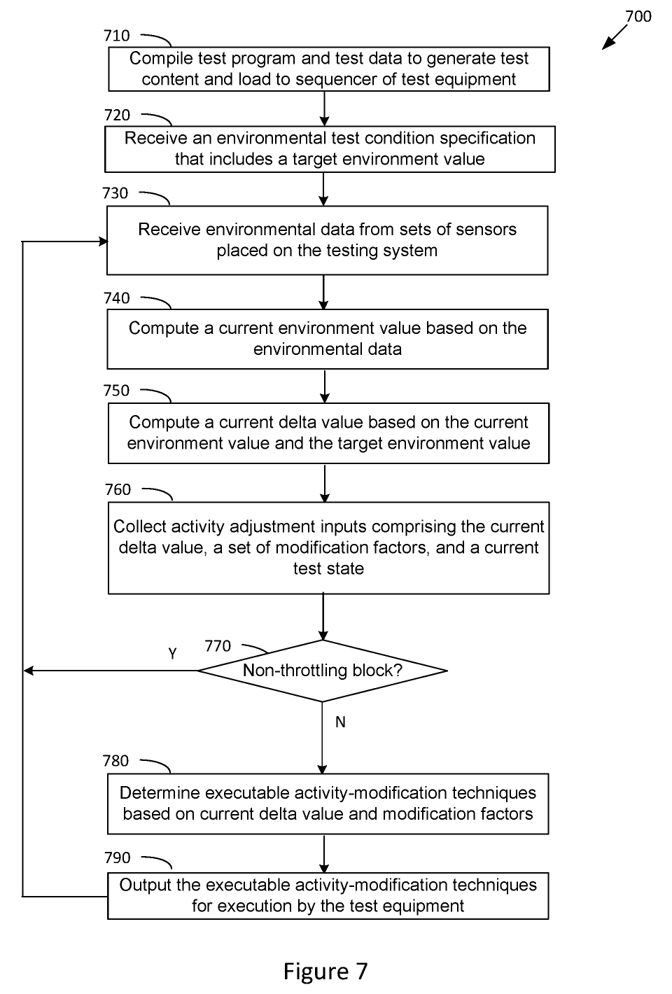

FIG. 7 is a flow diagram of method steps for maintaining correct environmental test conditions during testing of a DUT 150, according to various embodiments. Although the method steps are described in conjunction with the embodiments of FIGS. 1-5, persons of ordinary skill in the art will understand that any system configured to perform the method steps, in any order, is within the scope of the invention. In some embodiments, the method 700 is performed by a testing system 100 that implements a fine-grained control loop 300 while the testing system 100 concurrently performs testing of the DUT 150. The fine-grained control loop 300 can be implemented in software (e.g. via a control-loop application 130) or be implemented (partially or wholly) in hardware. In some embodiments, the testing system 100 can include multiple instances of the test equipment 110 that operate in conjunction and in synchronization to perform the method 700.

The method 700 begins at step 710, to initiate the testing of the DUT 150, the workstation 102 compiles the test program 104 and test data 106 to generate test content 180 that represents the test program 104 and test data 106. The test content 180 includes the block metadata generated for the test data 106 that specify the separate blocks 210, the throttling/non-throttling blocks 210, and the intensity level for each block 210. The test content 180 is also transmitted to the test equipment 110 and stored to the memory unit 122, whereby the test content 180 is loaded into the sequencer 134 (processor cache) of the processor 120. The test content 180 is executed by the test equipment 110 to perform testing of the DUT 150 while the method 700 described herein is concurrently performed to maintain the correct environmental test conditions throughout the testing period of the DUT 150.

At step 720, the controller error processing 330 receives an environmental test condition specification 310 that includes a specification for the correct environmental test conditions, which includes at least one target environment value, for example, from a customer, such as an entity that desires testing of the DUT 150.

At step 730, the sensor processing 320 receives a set of environmental data 190 received from sets of sensors 170 placed at various locations on the testing system 100. The set of environmental data 190 represents the current environmental test conditions during a current time point of the DUT testing.

At step 740, the sensor processing 320 computes a current environment value 322 based on the set of environmental data 190. In some embodiments, the current environment value 322 comprises a single numerical value that represents a particular type of environmental data. In some embodiments, the sensor processing 320 analyzes past and current sets of environmental data 190 to determine one or more predictive environmental trends that can be used to adjust upwards to downwards the current environment value 322.

At step 750, the controller error processing 330 computes a current delta value 332 comprising a difference between the current environment value 322 and the target environment value. The controller error processing 330 then transmits the current delta value 332 to the DUT activity adjustment 340.

At step 760, the DUT activity adjustment 340 collects/receives as input the current delta value 332, a set of modification factors 350, and a current test state 352. In some embodiments, the set of modification factors 350 can include the intensity levels of a current block 210 that is currently being executed for testing the DUT 150 and at least one future block 210 that is subsequent to the current block 210, the intensity levels being identified from the block metadata associated with the current block 210 and at least one future block 210. In some embodiments, the modification factors 350 can include an identified trend relating to the delta value 332. In some embodiments, the modification factors 350 includes the characteristics of the DUT 150, the testing system 100, and/or the testing environment. The current test state 352 can be a throttling block 210, non-throttling block 210, or a breakpoint 220, which can be determined by analyzing the block metadata of the current block 210 and the test data 106/test content 180 currently stored in the sequencer 134.

At step 770, the DUT activity adjustment 340 determines if the current test state 352 indicates that a current block 210 being executed for testing the DUT 150 is identified as a non-throttling block 210. As discussed above, the execution of a non-throttling block 210 for testing the DUT 150 cannot be interrupted by an activity-modification technique. If so (at step 760 – Yes), the method 700 continues to step 730, which effectively prevents execution of any activity-modification techniques in the current iteration of the fine-grained control loop 300. If not (at step 760 – No), the method 700 continues to step 780, which thereby permits execution of one or more activity-modification techniques in the current iteration of the fine-grained control loop 300.

At step 780, the DUT activity adjustment 340 determines a set of one or more executable activity-modification techniques 360 (including an amount for each activity-modification technique) based on the current delta value 332 and the modification factors 350. In particular, the DUT activity adjustment 340 can determine an initial amount of each activity-modification technique based on the current delta value 332, and then can modify the initial amount of each activity-modification technique based on one or more of the modification factors 350 to generate a final amount of each activity-modification technique. The final amount of each activity-modification technique is then included in the set of executable activity-modification techniques 360.

At step 790, the DUT activity adjustment 340 outputs the set of executable activity-modification techniques 360 for execution by the test equipment 110. When executed, the set of executable activity-modification techniques 360 will change the activity level of the DUT 150, which in turn will cause the current environmental test conditions (reflected in the set of environmental data 190) to advance/progress towards the correct environmental test conditions. The method 700 then continues at step 730 where the sensor processing 320 receives the set of environmental data 190 from the sets of sensors 170. The method 700 repeats in this feedback loop (from steps 730 to 790) until testing of the DUT 150 finishes/ends so that the correct environmental test conditions are maintained throughout the testing period of the DUT 150.

In sum, an automated testing system for a DUT is disclosed herein that provides real-time adjustments for an activity level of the DUT to ensure the correct/target environmental test conditions are maintained during the entire testing period. The correct/target environmental test conditions can be specified via one or more environmental targets and ranges. The one or more environmental targets and ranges can define targets and ranges for any type of environmental condition/parameter, such as a target temperature and temperature range, a target voltage and voltage range, a target power and power range, and the like. The testing system includes a set of sensors that generate a set of environmental data comprising one or more different types of environmental data, such as temperature data, voltage data, power data, and the like. The testing system can determine the current environmental test conditions based on the set of environmental data.

The testing system also implements a fine-grained control loop that, during the testing period, continuously determines if the actual/current environmental test conditions are in compliance with the correct environmental test conditions. If the testing system determines that the current environmental test conditions are not compliant with the correct environmental test conditions, the testing system determines one or more activity-modification techniques to be executed that advance/progress the actual environmental test conditions to be in compliance with the correct environmental test conditions. The one or more activity-modification techniques can increase or decrease the current activity level of the DUT.

At least one technical advantage of the disclosed techniques relative to the prior art is that the disclosed automated testing techniques provide continuous and real-time adjustments for an activity level of the DUT to ensure the correct/target environmental test conditions are maintained during the entire testing period. The techniques include a fine-grained feedback loop that continuously determines any difference/delta between the current environmental test conditions and the correct/target environmental test conditions, and continuously adjusts the activity level of the DUT using one or more activity-modification techniques. The techniques allow the activity level of the DUT to be adjusted continuously and in real-time to maintain the correct environmental test conditions more effectively relative to prior testing systems that implement coarse-grained throttling techniques that typically cannot continuously maintain the correct environmental test conditions throughout the testing period.

Another technical advantage is that the disclosed testing system determines the extent of the one or more activity-modification techniques based on the computed difference/delta with the correct environmental test conditions, intensity levels of a current block and one or more future blocks of test data, characteristics of the particular DUT, the testing system, and/or the testing environment, and/or one or more predictive factors, which causes more accurate changes to the current environmental test conditions relative to prior testing systems that only considered the computed difference/delta with the correct environmental test conditions. As such, the disclosed techniques can proactively anticipate changes in the environmental test conditions providing better control of the environmental test conditions before the environmental test conditions are out of a target range of the correct environmental test conditions. A further technical advantage is that the disclosed testing system can implement one or more activity-modification techniques that involve directly regulating the control parameters of the DUT which provide greater ability to change the current environmental test conditions relative to prior testing systems that only adjusted the parameters of the device cooling system. These technical advantages provide one or more technological advancements over prior art approaches.

Aspects of the subject matter described herein are set out in the following numbered clauses.

1. In some embodiments, a method for maintaining a target environmental test condition during testing of a device under test (DUT) comprises determining a first intensity level associated with a current block of test data, the first intensity level indicating an amount of resources needed by the DUT to execute the current block of test data, determining an amount of an activity-modification technique based, at least in part, on the first intensity level, and executing the amount of the activity-modification technique to change an activity level of the DUT.

2. The method of clause 1, wherein the amount of the activity-modification technique specifies a number of wait cycles for a throttling interval to be inserted in the test data.

3. The method of clauses 1 or 2, wherein the amount of the activity-modification technique specifies an adjustment value to be applied for at least one of a clock frequency, a voltage, current, or a power of the DUT.

4. The method of any of clauses 1-3, wherein the target environmental test condition comprises at least one of a target temperature, a target voltage, a target current, or a target power of the DUT.

5. The method of any of clauses 1-4, wherein the amount of the activity-modification technique is further based on a second intensity level associated with a future block of test data that is to be executed by the DUT subsequent to the current block of test data.

6. The method of any of clauses 1-5, wherein the amount of the activity-modification technique is further based on at least one of an electrical property of the DUT, an electrical property of testing equipment implemented for testing the DUT, or a current environmental condition of a testing environment in which the DUT is tested.

7. The method of any of clauses 1-6, further comprising determining a current environmental test condition based, at least in part, on environmental data received from a set of sensors, and computing a difference between the current environmental test condition and the target environmental test condition, wherein the amount of the activity-modification technique is further based on the difference.

8. The method of any of clauses 1-7, wherein the current environmental test condition is further determined based on an identified predictive trend associated with the current environmental test condition.

9. The method of any of clauses 1-8, wherein executing the amount of the activity-modification technique causes the current environmental test condition to move towards the target environmental test condition.

10. The method of any of clauses 1-9, wherein executing the amount of the activity-modification technique causes a change in at least one of a workload of the DUT, a duty cycle of the DUT, or a rate of testing the DUT.

11. The method of any of clauses 1-10, further comprising, before determining the amount of the activity-modification technique, determining that the current block of test data is identified as a throttling block that can be interrupted by an activity-modification technique.

12. In some embodiments, a testing system comprises a test equipment, and a test interface coupled to the test equipment, wherein the test equipment is configured to maintain a target environmental test condition during testing of a device under test (DUT) by performing the steps of determining a first intensity level associated with a current block of test data, the first intensity level indicating an amount of resources needed by the DUT to execute the current block of test data, determining an amount of an activity-modification technique based, at least in part, on the first intensity level, and executing the amount of the activity-modification technique to change an activity level of the DUT.

13. The testing system of clause 12, wherein the amount of the activity-modification technique specifies a number of wait cycles for a throttling interval to be inserted in the test data.

14. The testing system of clauses 12 or 13, wherein the amount of the activity-modification technique specifies an adjustment value to be applied for at least one of a clock frequency, a voltage, a current, or a power of the DUT.

15. The testing system of any of clauses 12-14, wherein the amount of the activity-modification technique is further based on a second intensity level associated with a future block of test data that is to be executed by the DUT subsequent to the current block of test data.

16. The testing system of any of clauses 12-15, further comprising determining a current environmental test condition based, at least in part, on environmental data received from a set of sensors, and computing a difference between the current environmental test condition and the target environmental test condition, wherein the amount of the activity-modification technique is further based on the difference.

17. The testing system of any of clauses 12-16, wherein the amount of the activity-modification technique specifies a number of wait cycles for a throttling interval, and executing the amount of the activity-modification technique comprises inserting the throttling interval in the test data via a switch that switches the testing of the DUT between the test data and a series of wait cycles.

18. The testing system of any of clauses 12-17, wherein the test data is stored in a first sequencer coupled to a first input of the switch, the series of wait cycles is stored in a second sequencer coupled to a second input of the switch, and an output of the switch outputs the test data stored in the first sequencer or the series of wait cycles stored in the second sequencer based on a control signal.

19. In some embodiments, one or more non-transitory computer-readable media store program instructions that, when executed by one or more processors, cause the one or more processors to maintain a target environmental test condition during testing of a device under test (DUT) by performing a set of steps comprising determining a first intensity level associated with a current block of test data, the first intensity level indicating an amount of resources needed by the DUT to execute the current block of test data, determining an amount of an activity-modification technique based, at least in part, on the first intensity level, and executing the amount of the activity-modification technique to change an activity level of the DUT.

20. The one or more non-transitory computer-readable media of clause 19, wherein the first intensity level is based on multiple executions of the current block of test data by the DUT and at least one different DUT.

Any and all combinations of any of the claim elements recited in any of the claims and/or any elements described in this application, in any fashion, fall within the contemplated scope of the present invention and protection.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

Aspects of the present embodiments may be embodied as a system, method, or computer program product. Accordingly, aspects of the present disclosure may take the form of an entirely hardware embodiment, an entirely software embodiment (including firmware, resident software, micro-code, etc.) or an embodiment combining software and hardware aspects that may all generally be referred to herein as a “module,” a “system,” or a “computer.” In addition, any hardware and/or software technique, process, function, component, engine, module, or system described in the present disclosure may be implemented as a circuit or set of circuits. Furthermore, aspects of the present disclosure may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Aspects of the present disclosure are described above with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine. The instructions, when executed via the processor of the computer or other programmable data processing apparatus, enable the implementation of the functions/acts specified in the flowchart and/or block diagram block or blocks. Such processors may be, without limitation, general purpose processors, special-purpose processors, application-specific processors, or field-programmable gate arrays.

The flowchart and block diagrams in the figures illustrate the architecture, functionality, and operation of possible implementations of systems, methods, and computer program products according to various embodiments of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

While the preceding is directed to embodiments of the present disclosure, other and further embodiments of the disclosure may be devised without departing from the basic scope thereof, and the scope thereof is determined by the claims that follow.

What is claimed is:

1. A method for maintaining a target environmental test condition during testing of a device under test (DUT), the method comprising:
determining a first intensity level associated with a current block of test data, the first intensity level indicating an amount of resources needed by the DUT to execute the current block of test data;
determining an amount of an activity-modification technique based, at least in part, on the first intensity level; and
executing the amount of the activity-modification technique to change an activity level of the DUT.

2. The method of claim 1, wherein the amount of the activity-modification technique specifies a number of wait cycles for a throttling interval to be inserted in the test data.

3. The method of claim 1, wherein the amount of the activity-modification technique specifies an adjustment value to be applied for at least one of a clock frequency, a voltage, current, or a power of the DUT.

4. The method of claim 1, wherein the target environmental test condition comprises at least one of a target temperature, a target voltage, a target current, or a target power of the DUT.

5. The method of claim 1, wherein the amount of the activity-modification technique is further based on a second intensity level associated with a future block of test data that is to be executed by the DUT subsequent to the current block of test data.

6. The method of claim 1, wherein the amount of the activity-modification technique is further based on at least one of an electrical property of the DUT, an electrical property of testing equipment implemented for testing the DUT, or a current environmental condition of a testing environment in which the DUT is tested.

7. The method of claim 1, further comprising:
determining a current environmental test condition based, at least in part, on environmental data received from a set of sensors; and
computing a difference between the current environmental test condition and the target environmental test condition, wherein the amount of the activity-modification technique is further based on the difference.

8. The method of claim 7, wherein the current environmental test condition is further determined based on an identified predictive trend associated with the current environmental test condition.

9. The method of claim 7, wherein executing the amount of the activity-modification technique causes the current environmental test condition to move towards the target environmental test condition.

10. The method of claim 1, wherein executing the amount of the activity-modification technique causes a change in at least one of a workload of the DUT, a duty cycle of the DUT, or a rate of testing the DUT.

11. The method of claim 1, further comprising, before determining the amount of the activity-modification technique, determining that the current block of test data is identified as a throttling block that can be interrupted by an activity-modification technique.

12. A testing system comprising:
a test equipment; and
a test interface coupled to the test equipment;
wherein the test equipment is configured to maintain a target environmental test condition during testing of a device under test (DUT) by performing the steps of:
determining a first intensity level associated with a current block of test data, the first intensity level indicating an amount of resources needed by the DUT to execute the current block of test data;
determining an amount of an activity-modification technique based, at least in part, on the first intensity level; and
executing the amount of the activity-modification technique to change an activity level of the DUT.

13. The testing system of claim 12, wherein the amount of the activity-modification technique specifies a number of wait cycles for a throttling interval to be inserted in the test data.

14. The testing system of claim 12, wherein the amount of the activity-modification technique specifies an adjustment value to be applied for at least one of a clock frequency, a voltage, a current, or a power of the DUT.

15. The testing system of claim 12, wherein the amount of the activity-modification technique is further based on a second intensity level associated with a future block of test data that is to be executed by the DUT subsequent to the current block of test data.

16. The testing system of claim 12, further comprising:
determining a current environmental test condition based, at least in part, on environmental data received from a set of sensors; and
computing a difference between the current environmental test condition and the target environmental test condition, wherein the amount of the activity-modification technique is further based on the difference.

17. The testing system of claim 12, wherein:
the amount of the activity-modification technique specifies a number of wait cycles for a throttling interval; and
executing the amount of the activity-modification technique comprises inserting the throttling interval in the test data via a switch that switches the testing of the DUT between the test data and a series of wait cycles.

18. The testing system of claim 17, wherein the test data is stored in a first sequencer coupled to a first input of the switch, the series of wait cycles is stored in a second sequencer coupled to a second input of the switch, and an output of the switch outputs the test data stored in the first sequencer or the series of wait cycles stored in the second sequencer based on a control signal.

19. One or more non-transitory computer-readable media storing program instructions that, when executed by one or more processors, cause the one or more processors to maintain a target environmental test condition during testing of a device under test (DUT) by performing a set of steps comprising:
determining a first intensity level associated with a current block of test data, the first intensity level indicating an amount of resources needed by the DUT to execute the current block of test data;
determining an amount of an activity-modification technique based, at least in part, on the first intensity level; and
executing the amount of the activity-modification technique to change an activity level of the DUT.

20. The one or more non-transitory computer-readable media of claim 19, wherein the first intensity level is based on multiple executions of the current block of test data by the DUT and at least one different DUT.
